(19) United States
(12) Patent Application Publication
(10) Pub. No.: US 2008/0061328 A1
(43) Pub. Date: Mar. 13, 2008

(54) CMOS IMAGE SENSOR USING SURFACE FIELD EFFECT

(76) Inventor: Byung-Tak Jang, Gyeonggi-do (KR)

Correspondence Address: SHERR & NOURSE, PLLC, 620 HERNDON PARKWAY, SUITE 200, HERNDON, VA, 20170, US

(21) Appl. No.: 11/847,624

(22) Filed: Aug. 30, 2007

(30) Foreign Application Priority Data
Sep. 12, 2006 (KR) 10-2006-0087736

(51) Int. Cl. H01L 31/113; H01L 21/00

(52) U.S. Cl. 257/292; 438/60; 257/E31.083; 257/E21.001

(57) ABSTRACT

A CMOS image sensor including a photodiode having a well having a first conductive type formed in a semiconductor substrate, a first ion-implantation layer formed in the semiconductor substrate having a conductive type being opposite to the first conductive type of the well, and a second ion-implantation layer having the first conductive type formed adjacent to the surface of the semiconductor substrate above the first ion-implantation layer. A transparent conductive electrode which is transparent to visible rays may be formed on the semiconductor substrate to cover the second ion-implantation layer.

The present application claims priority under 35 U.S.C. 119 to Korean Patent Application No. P2006-87736 (filed on Sep. 12, 2006), which is hereby incorporated by reference in its entirety.

### BACKGROUND

An image sensor is a semiconductor device used to convert optical images detected by the image sensor to electric signals. Image sensors may be classified as a charge coupled device (CCD) and a complementary metal oxide semiconductor (CMOS).

A CMOS image sensor is provided with MOS transistors whose number corresponds to the number of pixels of a semiconductor device having a control circuit and a signal processing circuit as peripheral circuits. The control circuit and the signal processing unit may be integrated together to employ a switching method that detects output through the MOS transistors.

A CMOS image sensor may be provided with a plurality of unit pixels whereby each unit pixel includes one light sensing device such as a photodiode and a plurality of MOS transistors.

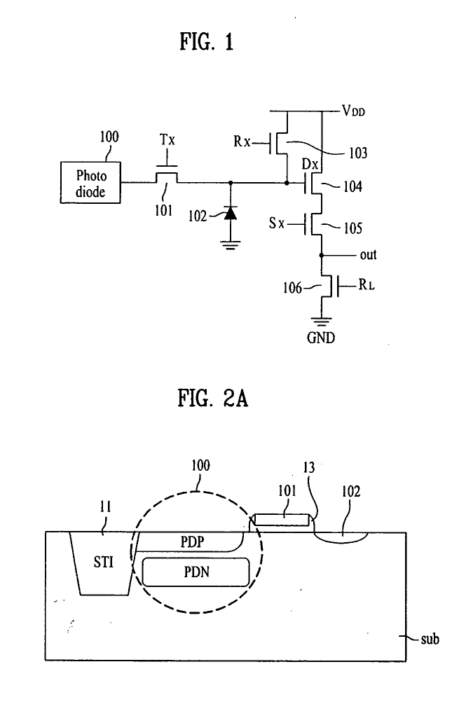

As illustrated in example FIG. 1, a CMOS image sensor includes photodiode 100 for sensing light and converting the light into optical charges. Transfer transistor 101 transfers the optical charges generated by photodiode 100 to floating diffusion region 102. Reset transistor 103 sets the electric potential of floating diffusion region 102 to a predetermined value, and also resets floating diffusion region 102 by discharging the optical charges. Drive transistor 104 acts as a source follower buffer amplifier while select transistor 105 is provided for switching and directing. Load transistor 106 is provided to read output charges, and is formed outside the unit pixel.

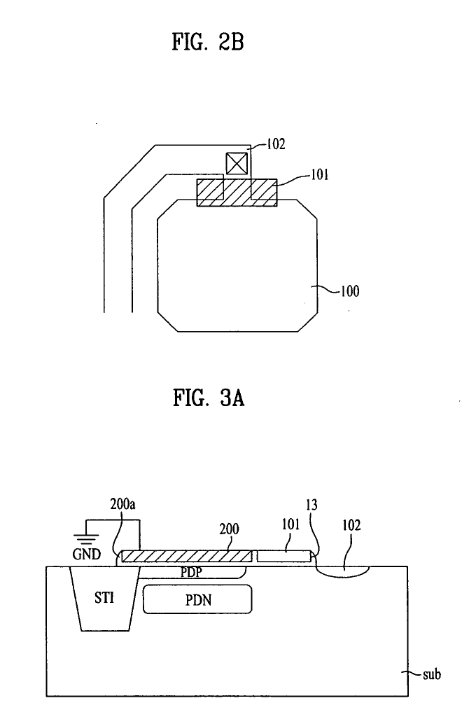

As illustrated in example FIG. 2A, a CMOS image sensor includes isolation film layer 11 formed in silicon substrate (Sub). Isolation film 11 may include a field oxide film. Gate electrode 101 of the transfer transistor includes a spacer which is formed on silicon substrate (Sub). Photodiode 100 includes N-type ion-implantation region (PDN) and P-type ion-implantation region (PDP). A P-well formed in silicon substrate (Sub) functions as a ground anode of PN diode, and the N-type ion-implantation region (PDN) functions as a cathode of PN diode.

As illustrated in example FIG. 2A, P-type ion-implantation region (PDP) is formed above N-type ion-implantation region (PDN) and adjacent to the upper surface of silicon substrate (Sub). N-type ion-implantation region (PDN) is not in direct contact with the upper surface of silicon substrate (Sub), and thus, is buried in silicon substrate (Sub). Consequently, the upper surface of silicon substrate (Sub) is not included in a depletion region of PN diode, thereby decreasing a leakage current caused by a dark current.

As illustrated in example FIG. 2A, the PN diode is formed below gate electrode 101 of the transfer transistor. Even though the transfer transistor is in an on state, there may be a high possibility that an energy barrier occurs between the photodiode and the transfer transistor. Accordingly, because the PN diode is deeply formed inside silicon substrate (Sub), the sensitivity for a blue color decreases.

P-type ion-implantation region (PDP) and the N-type ion-implantation region (PDN) may be formed in closer spatial proximity to the upper surface of silicon substrate. Particularly, high-density ions such as boron (B) or BF₂ are implanted into P-type ion-implantation region (PDP). The high-density ions of boron (B) or BF₂, which have great mobility, are diffused to N-type ion-implantation region (PDN) or transfer transistor, whereby their circumferential area is changed in doping density. In order to form PN junction adjacent to the upper surface of silicon substrate (Sub), it is important to lower the doping density of P-type ion-implantation region (PDP).

### SUMMARY

Embodiment relate to a CMOS image sensor including an MOS transistor having a photodiode including a well having a first conductive type formed in a semiconductor substrate. A first ion-implantation layer formed in the semiconductor substrate having a conductive type opposite to the first conductive type of the well. A second ion-implantation layer having the first conductive type, is formed adjacent to the surface of the semiconductor substrate above the first ion-implantation layer. A conductive electrode which is transparent to visible rays, is formed on the semiconductor substrate to cover the second ion-implantation layer having the first conductive type.

In accordance with embodiments, placement of a PN junction of a photodiode adjacent to an upper surface of a silicon substrate prevent dark currents by some of the ion-implantation layer coming into a depletion region of the PN junction.

### DRAWINGS

Example FIG. 1 illustrates a 4Tr-structure CMOS image sensor.

Example FIGS. 2A and 2B illustrate a photodiode region in a 4Tr-structure CMOS image sensor.

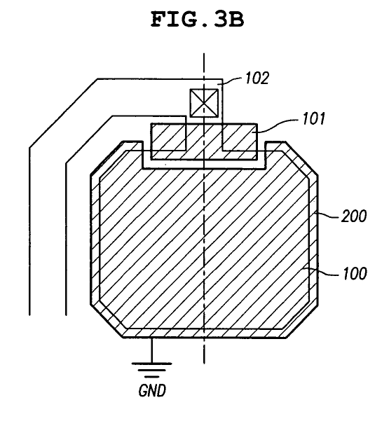

Example FIGS. 3A and 3B illustrate a photodiode region in a CMOS image sensor including a transparent electrode, in accordance with embodiments.

### DESCRIPTION

As illustrated in example FIGS. 3A and 3B, a first conductive type dopant, i.e., P-type, is ion-implanted into P-type silicon semiconductor substrate (Sub) to form a well. An N-type dopant may then be ion-implanted into substrate (Sub) forming first ion-implantation layer (PDN).

Ions such as boron B or BF₂ may be implanted adjacent to the upper surface of substrate (Sub) and may correspond to a predetermined height above first ion-implantation layer (PDN) to form P-type ion-implantation layer (PDP). Transfer transistor 101 including spacer 13 and floating diffusion region 102 are formed on and/or over substrate (Sub).

As illustrated in example FIGS. 3A and 3B, in the CMOS image sensor in accordance with embodiments, insulation film layer 200a is formed on and/or over P-type ion-implantation layer (PDP) to form conductive electrode 200. Insulating film layer 200a may be composed of silicon oxide. Moreover, such a silicon oxide film 200a may be formed of a material that is transparent to visible rays. Conductive electrode 200 may be composed of a transparent material capable of transmitting light to a photo-receiving part. Conductive electrode 200 may be formed on and/or over the upper surface of substrate (Sub). Insulating film 200a of silicon oxide may be interposed between transparent conductive electrode 200 and P-type ion-implantation layer (PDP). Particularly, transparent conductive electrode 200 is deposited on and/or over substrate (Sub) so that it covers the entire photodiode region, i.e., PDP and PDN.

As illustrated in example FIGS. 3A and 3B, placement of conductive electrode 200 on and/or over PDP region of the photodiode will result in it having no effects on light transmittance, and thus, the visible rays of the desired wavelength are concentrated on the photodiode.

Ground potential (GND) may be applied to the conductive electrode 200 in order that positive charges (holes) of PDP region are induced to the conductive electrode 200. Meaning, the positive charges of PDP region are induced to the upper side of the ion-implantation layer, i.e., the upper surface of silicon substrate (Sub), much like the induction of positive charges to the upper surface of a substrate in a P-MOSFET.

As the positive charges are induced to the upper surface of silicon substrate (Sub) by the field effect, there is no requirement for highly-doped PDP region. Accordingly, the defective surface is not included in the depletion region of the photodiode, thereby preventing dark current.

In accordance with embodiments, while PDP region is doped with low density ions of boron or BF₂, the charges may still be induced to the upper surface of substrate (Sub) by the field effect. Accordingly, there is little chance that the junction of the photodiode is moved downward due to the boron or BF₂ ions having great mobility. Therefore, the PN junction may be formed adjacent to the uppermost surface of substrate (Sub).

The position of the PN junction may be determined based on the density of PDN, which is useful to the optimization of the fabrication process. In accordance to embodiments, the density of PDP region may be lower than what is typical. Thus, the current-voltage relation in the channel region of the transfer transistor may be rarely influenced by the density of PDP region.

In accordance with embodiments, a plurality of N-channel MOS transistors may be formed in a P-type semiconductor substrate. On the other hand, a plurality of P-type MOS transistors may be formed in an N-type semiconductor substrate, in which case conductive electrode 200 may be connected to a power voltage Vdd.

A CMOS image sensor in accordance with embodiments may yield a variety of advantages. For instance, by decreasing the density of the PDP region, the PN junction of the photodiode may be formed adjacent to the uppermost surface of the substrate. Current leakage caused by the defective surface of the substrate may be prevented. The energy barrier between the transfer transistor and the photodiode may also be lowered. The decrease in the energy barrier implies the decrease of time delay on reading the information of the photodiode, wand thus, enhances the efficiency of the CMOS image sensor.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a photodiode including a well having a first conductive type formed in a semiconductor substrate, a first ion-implantation layer formed in the semiconductor substrate having a conductive type opposite to the first conductive type of the well, and a second ion-implantation layer having the first conductive type, formed adjacent to the uppermost surface of the semiconductor substrate and above the first ion-implantation layer; and
a conductive electrode formed over the semiconductor substrate to cover the second ion-implantation layer, wherein the conductive electrode is transparent to visible rays.

2. The apparatus of claim 1, further comprising an insulation layer formed on the surface of the semiconductor substrate and interposed between the second ion-implantation layer and the conductive electrode.

3. The apparatus of claim 2, wherein the insulation layer is formed of an oxide layer.

4. The apparatus of claim 3, wherein the oxide layer is transparent to visible rays.

5. The apparatus of claim 1, wherein the semiconductor substrate is a P-type silicon substrate.

6. The apparatus of claim 5, wherein a P-type dopant is implanted into the well, an N-type dopant is implanted into the first ion-implantation layer, a P-type dopant is implanted into the second ion-implantation layer, and a MOS transistor corresponds to an NMOS transistor.

7. The apparatus of claim 6, wherein boron ions are implanted into the second ion-implantation layer.

8. The apparatus of claim 6, wherein BF₂ ions are implanted into the second ion-implantation layer.

9. The apparatus of claim 1, wherein the semiconductor substrate is a P-type substrate, a MOS transistor corresponds to an NMOS transistor, and the conductive electrode is connected to a ground potential.

10. The apparatus of claim 1, wherein the semiconductor substrate is an N-type silicon substrate, an N-type dopant is implanted into the well, a P-type dopant is implanted into the first ion-implantation layer, an N-type dopant is implanted into the second ion-implantation layer, and a MOS transistor corresponds to a PMOS transistor.

11. The apparatus of claim 1, wherein the semiconductor substrate is an N-type substrate, the MOS transistor corresponds to a PMOS transistor; and the conductive electrode is connected to a power voltage.

12. A method comprising:
forming a photodiode including a well having a first conductive type formed in a semiconductor substrate, a first ion-implantation layer formed in the semiconductor substrate having a conductive type opposite to the first conductive type of the well, and a second ion-implantation layer having the first conductive type, formed adjacent to the uppermost surface of the semiconductor substrate and above the first ion-implantation layer; and
forming a conductive electrode over the semiconductor substrate to cover the second ion-implantation layer, wherein the conductive electrode is transparent to visible rays.

13. The method of claim 12, further comprising forming an insulation layer on the surface of the semiconductor substrate between the second ion-implantation layer and the conductive electrode.

14. The method of claim 13, wherein the insulation layer is formed of an oxide layer that is transparent to visible rays.

15. The method of claim 12, wherein the semiconductor substrate is a P-type silicon substrate.

16. The method of claim 15, further comprising implanting a P-type dopant into the well, implanting an N-type dopant into the first ion-implantation layer, implanting a P-type dopant into the second ion-implantation layer

17. The method of claim 16, wherein a MOS transistor corresponds to an NMOS transistor.

18. The method of claim 17, wherein at least one of boron and BF₂ ions are implanted into the second ion-implantation layer.

19. The method of claim 12, wherein the semiconductor substrate is a P-type substrate, a MOS transistor corresponds to an NMOS transistor, and the conductive electrode is connected to a ground potential.

20. The method of claim 12, wherein the semiconductor substrate is an N-type silicon substrate, an N-type dopant is implanted into the well, a P-type dopant is implanted into the first ion-implantation layer, an N-type dopant is implanted into the second ion-implantation layer, and a MOS transistor corresponds to a PMOS transistor.
